(19) United States
(12) Patent Application Publication
(10) Pub. No.: US 2026/0031298 A1
(43) Pub. Date: Jan. 29, 2026

(54) ELECTRON BEAM ADJUSTMENT METHOD, ELECTRON BEAM WRITING APPARATUS, AND NON-TRANSITORY COMPUTER-READABLE STORAGE MEDIUM STORING A PROGRAM

(71) Applicant: NuFlare Technology, Inc., Yokohama-shi (JP)

(72) Inventors: Mitsuaki SUZUKI, Fujisawa-shi (JP); Soshi SUZUKI, Fujisawa-shi (JP)

(73) Assignee: NuFlare Technology, Inc., Yokohama-shi (JP)

(21) Appl. No.: 19/256,391

(22) Filed: Jul. 1, 2025

(30) Foreign Application Priority Data
Jul. 26, 2024 (JP) 2024-121668

(51) Int. Cl. H01J 37/07; H01J 37/24

(52) U.S. Cl. CPC H01J 37/07; H01J 37/243; H01J 2201/19

(57) ABSTRACT

An electron beam adjustment method includes measuring a current density distribution of an electron beam to reach a target object, calculating a feature amount of a measured current density distribution, and increasing, in the case of the feature amount being outside the range of a threshold, a temperature of an electron beam emission source.

### CROSS-REFERENCE TO RELATED APPLICATION

This application is based upon and claims the benefit of priority from prior Japanese Patent Application No. 2024-121668 filed on Jul. 26, 2024 in Japan, the entire contents of which are incorporated herein by reference.

### BACKGROUND OF THE INVENTION

### Field of the Invention

An aspect of an embodiment of the present invention relates to an electron beam adjustment method, an electron beam writing apparatus, and a program (or non-transitory computer-readable storage medium). For example, it relates to a method for adjusting operating conditions of a cathode of a thermal electron gun which emits electron beams.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” a mask pattern on a mask blank with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple-beam system forms multiple beams by letting an electron beam emitted from a thermal electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

In electron beam writing, electron beams emitted from the electron gun are periodically adjusted so that the current density of the entire electron beam may be in an acceptable range. For example, conventionally, adjustment is made such that the current density of the entire electron beam is periodically measured, and when the density is insufficient, the emission current is increased. If still insufficient, a cathode temperature is increased in order to obtain a desired value of the current density of the entire electron beam (e.g., refer to Japanese Patent Application Laid-open (JP-A) No. 2014-165075).

However, in the case of adjusting electron beams by the conventional method, when the surface of the target object is irradiated with the adjusted electron beams, a problem occurs in that a desired incident dose cannot be acquired depending on a part of the irradiated region.

### BRIEF SUMMARY OF THE INVENTION

According to one aspect of the present invention,

an electron beam adjustment method includes measuring a current density distribution of an electron beam to reach a target object, calculating a feature amount of a measured current density distribution, and increasing, in a case of the feature amount being outside a range of a threshold, a temperature of an electron beam emission source.

According to another aspect of the present invention, an electron beam writing apparatus includes a current density distribution measurement circuit configured to measure a current density distribution of an electron beam to reach a target object, a feature amount calculation circuit configured to calculate a feature amount of a measured current density distribution, a temperature increase circuit configured to increase, in a case of the feature amount being outside a range of a threshold, a temperature of an electron beam emission source, and a writing mechanism configured to write a pattern on the target object by using the electron beam whose feature amount is within the range of the threshold.

According to yet another aspect of the present invention, a non-transitory computer-readable storage medium storing a program for causing a computer to execute processing includes measuring a current density distribution of an electron beam to reach a target object, storing a measured current density distribution in a storage device, reading the measured current density distribution from the storage device and calculating a feature amount of the measured current density distribution, and increasing, in a case of the feature amount being outside a range of a threshold, a temperature of an electron beam emission source.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is an illustration showing an example of a current density distribution of an electron beam to reach on the surface of a target object according to the first embodiment;

FIG. 5 is a flowchart showing an example of main steps of a writing method according to the first embodiment;

FIG. 6 is an illustration showing an example of temporal transition of a feature amount according to the first embodiment;

FIG. 7 is an illustration showing an example of the course of an operating point of an electron gun due to electron beam adjustment according to the first embodiment;

FIG. 8 is an illustration showing an example of transition of a current density distribution due to electron beam adjustment according to the first embodiment;

FIG. 9 is a conceptual diagram illustrating an example of a writing operation according to the first embodiment;

FIG. 10 is an illustration showing an example of an irradiation region of multiple beams and a writing target pixel according to the first embodiment;

FIG. 11 is an illustration for explaining an example of a writing method of multiple beams according to the first embodiment;

FIG. 12 is a conceptual diagram showing a configuration of a writing apparatus according to a second embodiment;

FIG. 13 is an illustration for explaining a method of measuring a current density distribution according to the second embodiment; and

FIG. 14 is an illustration explaining a procedure for measuring a current density distribution according to the second embodiment.

### DETAILED DESCRIPTION OF THE INVENTION

An embodiment of the present invention provides a method and apparatus by which a necessary incident dose can be obtained at all of the electron beam irradiation regions.

In the embodiments below, multiple beams or a single beam may be used as an electron beam.

Furthermore, although a writing apparatus is described below, any other apparatus is also preferable as long as it uses electron beams emitted from an electron emission source. For example, it may be an image acquisition apparatus, an inspection apparatus, or the like.

### First Embodiment

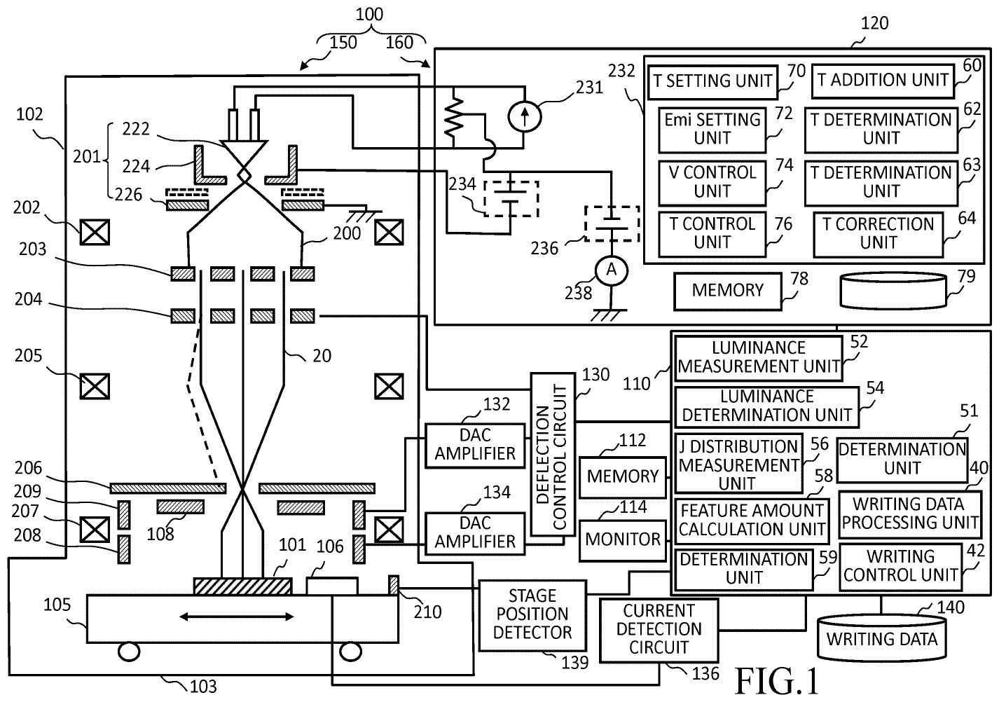

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multiple electron beam writing apparatus, and also an example of an electron beam writing apparatus. The writing mechanism 20 150 includes an electron optical column 102 (multiple electron beam column) and a writing chamber 103. In the electron optical column 102, there are disposed an electron gun 201 (thermal electron gun, thermal electron emission source), an illumination lens 202, a shaping aperture array substrate 203, 25 a blanking aperture array mechanism 204, a reducing lens 205, a limiting aperture substrate 206, an objective lens 207, a deflector 208, and a deflector 209. In the writing chamber 103, an XY stage 105 is disposed. On the XY stage 105, there is placed a target object or “sample” 101 such as a mask blank 30 on which resist has been applied serving as a writing target substrate when writing is performed. The target object 101 is, for example, an exposure mask used in fabricating semiconductor devices, or a semiconductor substrate (silicon wafer) for fabricating semiconductor devices. Furthermore, on the XY stage 105, a mirror 210 for measuring the position of the XY stage 105, and a Faraday cup 106 are placed.

The electron gun 201 (an example of a thermal electron gun or an electron beam emission source) includes a cathode 222 (another example of the electron beam emission source), an electrostatic electrode 224 (an electrode directly below the cathode, the electrostatic electrode 224 including, for example, a Wehnelt), and an anode 226 (anode electrode). The anode 226 is grounded. Between the electrostatic electrode 224 and the anode 226, one or more electrostatic electrodes (dotted line) may be arranged. The anode 226 is controlled to be a positive potential with respect to the cathode 222. The electrostatic electrode 224 is controlled to be a negative potential with respect to the cathode 222. The electron gun 201 emits an electron beam 200 toward the anode 226 from the cathode 222. An opening through which the electron beam 200 can pass is formed in the electrostatic electrode 224 and the anode 226 (and the electrostatic electrode (dotted line)).

The control system circuit 160 includes a control computer 110, a memory 112, a monitor 114, an electron gun power supply device 120, a deflection control circuit 130, DAC (digital-analog converter) amplifier units 132 and 134, a current detection circuit 136, a stage position detector 139, and a storage device 140 such as a magnetic disk drive. The control computer 110, the memory 112, the monitor 114, the electron gun power supply device 120, the deflection control circuit 130, the DAC amplifier units 132 and 134, the current detection circuit 136, the stage position detector 139, and the storage device 140 are connected to each other through a bus (not shown).

The DAC amplifier units 132 and 134 and the blanking aperture array mechanism 204 are connected to the deflection control circuit 130. Outputs of the DAC amplifier unit 132 are connected to the deflector 209. Outputs of the DAC amplifier unit 134 are connected to the deflector 208. The deflector 208 is composed of at least four electrodes (or “poles”), and each electrode is connected to the DAC amplifier 134 and controlled by the deflection control circuit 130 through the corresponding DAC amplifier 134. The deflector 209 is composed of at least four electrodes (or “poles”), and each electrode is connected to the DAC amplifier unit 132 and controlled by the deflection control circuit 130 through the corresponding DAC amplifier unit 132. The stage position detector 139 emits laser lights to the mirror 210 on the XY stage 105, and receives a reflected light from the mirror 210. The stage position detector 139 measures the position of the XY stage 105, based on the principle of laser interferometry which uses information of the reflected light. Outputs of the Faraday cup 106 are connected to the current detection circuit 136.

In the control computer 110, there are arranged a determination unit 51, a luminance measurement unit 52, a luminance determination unit 54, a current density distribution measurement unit 56, a feature amount calculation unit 58, a determination unit 59, a writing data processing unit 40, and a writing control unit 42. Each of the “ . . . units” such as the determination unit 51, the luminance measurement unit 52, the luminance determination unit 54, the current density distribution measurement unit 56, the feature amount calculation unit 58, the determination unit 59, the writing data processing unit 40, and the writing control unit 42 includes processing circuitry. As the processing circuitry, for example, an electric circuit, computer, processor, circuit board, quantum circuit, semiconductor device, or the like can be used. Each “ . . . unit” may use common processing circuitry (the same processing circuitry), or different processing circuitry (separate processing circuitry). Information input/output to/from the determination unit 51, the luminance measurement unit 52, the luminance determination unit 54, the current density distribution measurement unit 56, the feature amount calculation unit 58, the determination unit 59, the writing data processing unit 40, and the writing control unit 42, and information being operated are stored in the memory 112 each time.

In the electron gun power supply device 120, there are arranged a control computer 232, a memory 78, a storage device 79 such as a magnetic disk drive, an acceleration voltage power circuit 236, an electrostatic electrode voltage power circuit 234, a filament power supply circuit 231 (filament power supply unit), and an ammeter 238. To the control computer 232, there are connected the memory 78, the storage device 79, the acceleration voltage power circuit 236, the electrostatic electrode voltage power circuit 234, the filament power supply circuit 231, and the ammeter 238 through a bus (not shown).

In the control computer 232, there are arranged a cathode temperature addition unit 60, a cathode temperature determination unit 62, a cathode temperature determination unit 63, a cathode temperature correction unit 64, a cathode temperature setting unit 70, an emission current setting unit 72, an electrostatic electrode voltage control unit 74, and a cathode temperature control unit 76. Each of the “ . . . units” such as the cathode temperature addition unit 60, the cathode temperature determination unit 62, the cathode temperature determination unit 63, the cathode temperature correction unit 64, the cathode temperature setting unit 70, the emission current setting unit 72, the electrostatic electrode voltage control unit 74, and the cathode temperature control unit 76 includes processing circuitry. As the processing circuitry, for example, an electric circuit, computer, processor, circuit board, quantum circuit, semiconductor device, or the like can be used. Each “ . . . unit” may use common processing circuitry (the same processing circuitry), or different processing circuitry (separate processing circuitry). Information input/output to/from the cathode temperature addition unit 60, the cathode temperature determination unit 62, the cathode temperature determination unit 63, the cathode temperature correction unit 64, the cathode temperature setting unit 70, the emission current setting unit 72, the electrostatic electrode voltage control unit 74, and the cathode temperature control unit 76, and information being operated are stored in the memory 78 each time.

The negative electrode (−) side of the acceleration voltage power circuit 236 is connected to both poles of the cathode 222 in the electron optical column 102.

The positive electrode (+) side of the acceleration voltage power circuit 236 is grounded through the ammeter 238 connected in series. Furthermore, the negative electrode (−) of the acceleration voltage power circuit 236 branches to also be connected to the positive electrode (+) of the electrostatic electrode voltage power circuit 234. The negative electrode (−) of the electrostatic electrode voltage power circuit 234 is electrically connected to the electrostatic electrode 224 disposed between the cathode 222 and the anode 226. In other words, the electrostatic electrode voltage power circuit 234 is arranged to be electrically connected between the negative electrode (−) of the acceleration voltage power circuit 236 and the electrostatic electrode 224. Then, the filament power supply circuit 231 controlled by the cathode temperature control unit 76 supplies a current between both electrodes of the cathode 222 in order to heat the cathode 222 to a predetermined temperature. In other words, the filament power supply circuit 231 supplies a filament power W to the cathode 222. The filament power W and a cathode temperature T can be defined by a certain relation, and the cathode can be heated to a desired temperature T by the filament power W. Thus, the cathode temperature T is controlled by the filament power W. The filament power W is defined by the product of a current flowing between both electrodes of the cathode 222 and a voltage applied between both electrodes of the cathode 222 by the filament power supply circuit 231. The acceleration voltage power circuit 236 applies an acceleration voltage between the cathode 222 and the anode 226. The electrostatic electrode voltage power circuit 234 controlled by the electrostatic electrode voltage control unit 74 applies a negative electrostatic electrode voltage to the electrostatic electrode 224.

Writing data is input from the outside of the writing apparatus 100, and stored in the storage device 140. Writing data generally defines information on a plurality of figure patterns to be written. Specifically, for each figure pattern, vertex coordinates which form a figure are defined in order of forming the figure, for example. Alternatively, for each figure pattern, a figure code, reference position coordinates, a size, and the like are defined, for example.

FIG. 1 shows a configuration necessary for describing the first embodiment. Other configuration elements generally necessary for the writing apparatus 100 may also be included therein.

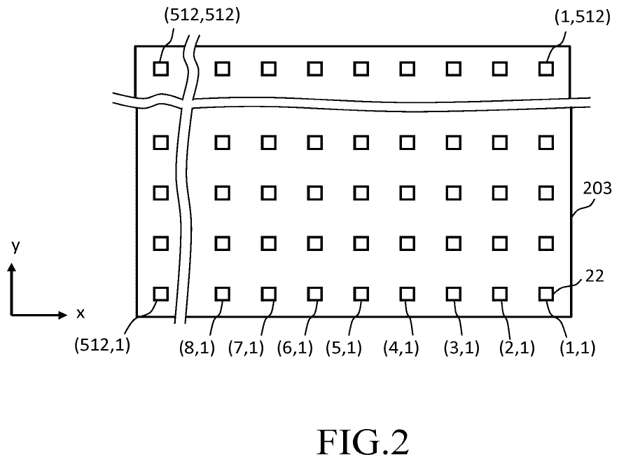

FIG. 2 is a conceptual diagram showing a configuration of the shaping aperture array substrate 203 according to the first embodiment. As shown in FIG. 2, holes (openings) 22 of p columns wide (width in the x direction) and q rows long (length in the y direction) (p≥2, q≥2) are formed, like a matrix, at a predetermined arrangement pitch in the shaping aperture array substrate 203. In the case of FIG. 2, for example, holes (openings) 22 of 512×512, that is 512 (rows arrayed in the y direction)×512 (columns aligned in the x direction), are formed. Each of the holes 22 is rectangular, including square, having the same dimension and shape as each other. Alternatively, each of the holes 22 may be a circle with the same diameter as each other. The shaping aperture array substrate 203 (beam forming mechanism) forms multiple beams 20. Specifically, the multiple beams 20 are formed by letting portions of the electron beam 200 individually pass through a corresponding one of a plurality of holes 22. The method of arranging the holes 22 is not limited to the case of FIG. 2 where the holes are arranged like a grid in the width and length directions. For example, with respect to the kth and (k+1) th rows which are arrayed in the length direction (in the y direction), each hole in the kth row and each hole in the (k+1) th row may be arranged mutually displaced in the width direction (in the x direction) by a dimension “a”. Similarly, with respect to the (k+1)th and (k+2)th rows which are arrayed in the length direction (in the y direction), each hole in the (k+1)th row and each hole in the (k+2)th row may be arranged mutually displaced in the width direction (in the x direction) by a dimension “b”.

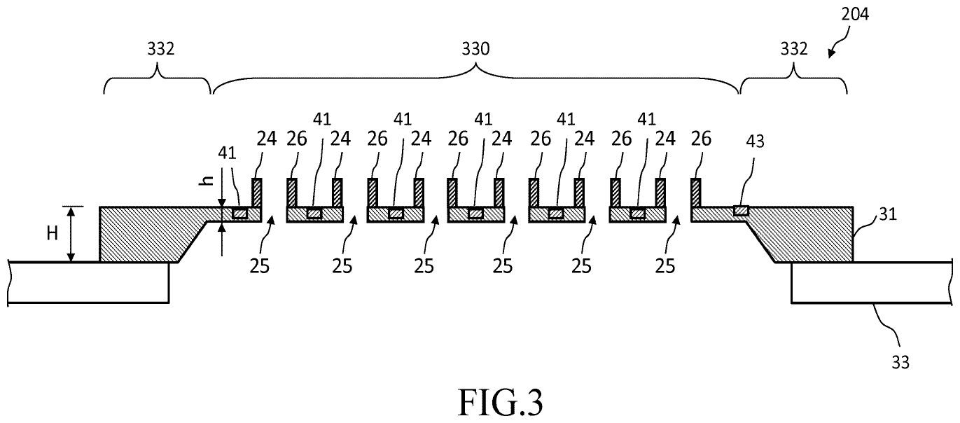

FIG. 3 is a sectional view showing a configuration of the blanking aperture array mechanism 204 according to the first embodiment. With regard to the configuration of the blanking aperture array mechanism 204, a semiconductor substrate 31 made of silicon, etc. is placed on a support table 33 as shown in FIG. 3. The central part of the substrate 31 is shaved, for example, from the back side and processed into a membrane region 330 (first region) having a thin film thickness h. The periphery surrounding the membrane region 330 is an outer peripheral region 332 (second region) having a thick film thickness H. The upper surface of the membrane region 330 and the upper surface of the outer peripheral region 332 are formed to be flush (same height) or substantially flush with one another. At the back side of the outer peripheral region 332, the substrate 31 is supported on the support table 33. The central part of the support table 33 is open, and the membrane region 330 is located at this opening region.

In the membrane region 330, passage holes 25 (openings) through each of which a corresponding one of the multiple beams 20 passes are formed at positions each corresponding to each hole 22 in the shaping aperture array substrate 203 shown in FIG. 2. In other words, in the membrane region 330 of the substrate 31, there are formed a plurality of passage holes 25, in an array state, through each of which a corresponding one of the multiple electron beams 20 passes. Furthermore, on the membrane region 330 of the substrate 31, there are arranged a plurality of electrode pairs each composed of two electrodes being opposite to each other across a corresponding one of a plurality of passage holes 25. Specifically, on the membrane region 330, as shown in FIG. 3, each pair of a control electrode 24 and a counter electrode 26 (blanker: blanking deflector) for blanking deflection is arranged close to a corresponding passage hole 25 in a manner such that the electrodes 24 and 26 are opposite to each other across the passage hole 25 concerned. Furthermore, close to each passage hole 25 in the membrane region 330, inside the substrate 31, there is arranged a control circuit 41 (logic circuit) which applies a deflection voltage to the control electrode 24 for the passage hole 25 concerned. The counter electrode 26 for each beam is grounded.

In the control circuit 41, there is arranged an amplifier (an example of a switching circuit) (not shown) such as a CMOS inverter circuit. The output line (OUT) of the amplifier is connected to the control electrode 24. On the other hand, the counter electrode 26 is applied with a ground electric potential. Regarding an input (IN) to the amplifier, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the amplifier, the output (OUT) of the amplifier becomes a positive potential (Vdd), and then, a corresponding beam is deflected by an electric field due to a potential difference from the ground potential of the counter electrode 26 so as to be blocked by the limiting aperture substrate 206, and thus it is controlled to be in a beam OFF condition. In contrast, in a state (active state) where an H potential is applied to the input (IN) of the amplifier, the output (OUT) of the amplifier becomes a ground potential, and therefore, since there is no potential difference from the ground potential of the counter electrode 26, a corresponding beam is not deflected, and controlled to be in a beam ON condition by passing through the limiting aperture substrate 206.

A pair of the control electrode 24 and the counter electrode 26 individually blanking deflects a corresponding beam of the multiple beams 20 by an electric potential switchable by the amplifier which serves as a corresponding switching circuit. Thus, each of a plurality of blankers performs blanking deflection of a corresponding beam in the multiple beams 20 having passed through a plurality of holes 22 (openings) in the shaping aperture array substrate 203.

Next, operations of the writing mechanism 150 of the writing apparatus 100 will be described. The electron beam 200 emitted from the electron gun 201 (electron emission source) illuminates the whole of the shaping aperture array substrate 203 by the illumination lens 202. A plurality of quadrangular (rectangular) holes 22 (openings) are formed in the shaping aperture array substrate 203. The region including all of the plurality of holes 22 is irradiated with the electron beam 200. For example, a plurality of quadrangular (rectangular) electron beams (multiple beams 20) are formed by letting portions of the electron beam 200 applied to the positions of the plurality of holes 22 individually pass through a corresponding hole of the plurality of holes 22 in the shaping aperture array substrate 203. The multiple beams 20 individually pass through corresponding blankers (first deflector: individual blanking mechanism) of the blanking aperture array mechanism 204. Each blanker deflects (provides blanking deflection) an electron beam passing individually therethrough.

The multiple beams 20 having passed through the blanking aperture array mechanism 204 are reduced by the reducing lens 205, and travel toward the hole in the center of the limiting aperture substrate 206. Then, the electron beam in the multiple beams 20 which was deflected by the blanker of the blanking aperture array mechanism 204 deviates from the hole in the center of the limiting substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Blanking control is provided by ON/OFF of the individual blanking mechanism so as to control ON/OFF of beams. Then, for each beam, one shot beam is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, respective beams having passed (all of the multiple beams 20 having passed) through the limiting aperture substrate 206 are collectively deflected in the same direction by the deflectors 208 and 209 in order to irradiate respective beam irradiation positions on the target object 101. Ideally, the multiple beams 20 irradiating at a time are aligned at the pitch obtained by multiplying the arrangement pitch of a plurality of holes 22 in the shaping aperture array substrate 203 by a desired reduction ratio described above.

With regard to the electron gun 201 which emits electron beams, as described above, there are many cases where, in order to obtain an emission current serving as an electron beam of a desired luminance with the lowest possible cathode temperature, the operating point of the electron gun 201 is set at the position close to the border between a space charge limited region and a temperature limited region and not within the temperature limited region.

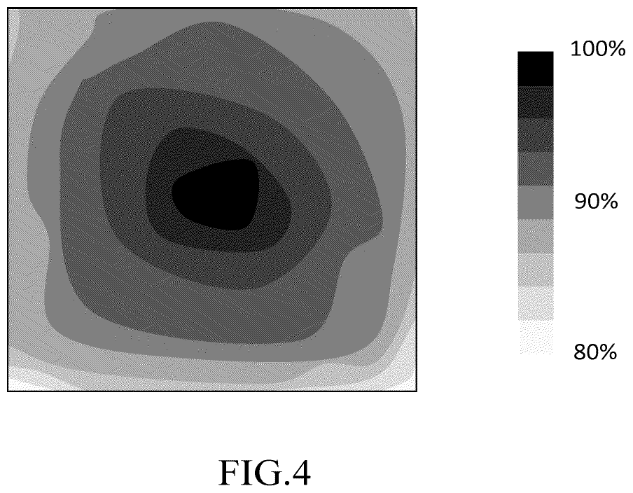

FIG. 4 is an illustration showing an example of a current density distribution of an electron beam to reach on the surface of a target object according to the first embodiment. As shown in FIG. 4, it turns out that even when the current density of the entire electron beam satisfies a desired value, the current density varies depending on the position in the entire beam. Therefore, even when the target object 101 is irradiated with an electron beam, an incident dose (dose amount) varies depending on the position in the irradiated region. In the case of FIG. 4, it turns out that the closer to the outer peripheral side, the smaller the current density. The multiple beams 20 particularly have a tendency that the current densities of the electron beams close to the four corners of the beam array of the multiple beams 20 are smaller than that of electron beam at the central part.

Conventionally, in electron beam writing, adjustment of an electron beam emitted from the electron gun has been periodically made so that the current density of the entire electron beam may be within an acceptable range. For example, conventionally, in order to obtain a desired value of the current density of the entire electron beam, adjustment has been made by periodically measuring the current density of the entire electron beam, and increasing the emission current when the current density is insufficient, and if still insufficient, the cathode temperature is increased.

However, when adjusting electron beams by the conventional method, although the current density of the entire beam is monitored, a current density distribution which depends on the position in the beam irradiation region is not monitored. Therefore, even if the surface of the target object is irradiated with an adjusted electron beam, a desired incident dose cannot be obtained depending on a portion such as the outer peripheral portion in an irradiated region.

Then, according to the first embodiment, not only the current density of the entire beam but also a current density distribution of an irradiating electron beam is measured for performing an adjustment of electron beams in accordance with the current density distribution. It is specifically described below.

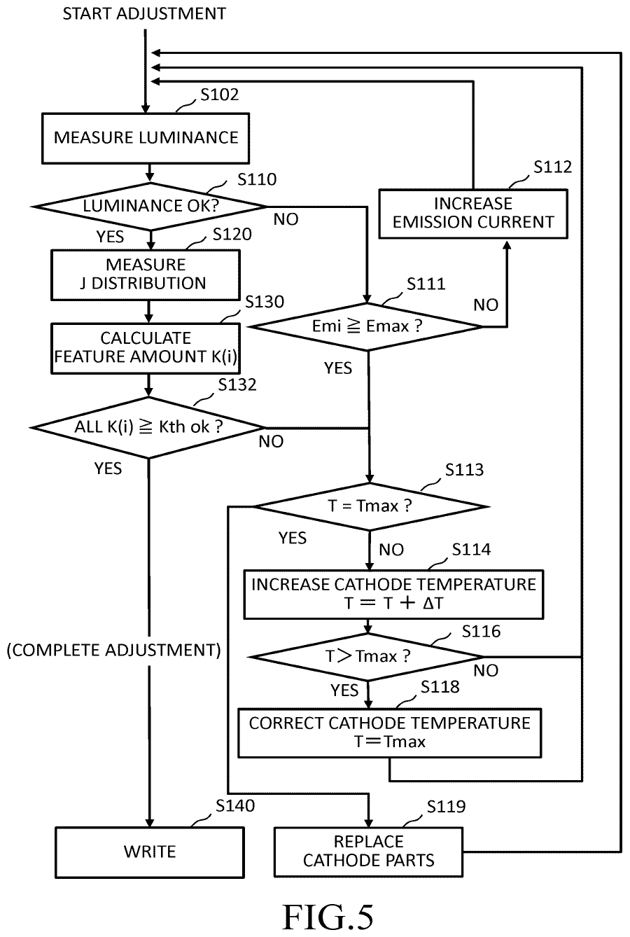

FIG. 5 is a flowchart showing an example of main steps of a writing method according to the first embodiment. In FIG. 5, the writing method of the first embodiment executes a series of steps: a luminance measurement step (S102), a determination step (S110), an emission current determination step (S111), an emission current increase step (S112), a cathode temperature determination step (S113), a cathode temperature increase step (S114), a cathode temperature determination step (S116), a cathode temperature correction step (S118), a cathode parts replacement step (S119), a current density distribution measurement step (S120), a feature amount calculation step (S130), a determination step (S132), and a writing step (S140). In the flowchart of FIG. 5, the electron beam adjustment method executes the luminance measurement step (S102), the determination step (S110), the emission current determination step (S111), the emission current increase step (S112), the cathode temperature determination step (S113), the cathode temperature increase step (S114), the cathode temperature determination step (S116), the cathode temperature correction step (S118), the cathode parts replacement step (S119), the current density distribution measurement step (S120), the feature amount calculation step (S130), and the determination step (S132). The electron beam adjustment is performed periodically, such as every week. Although it is preferable to perform the cathode parts replacement step (S119), it may be omitted.

In the luminance measurement step (S102), the luminance measurement unit 52 measures luminance of the entire multiple beams 20. Here, as a parameter indicating the luminance, a current density J of the entire multiple beams 20 is measured. Concretely, first, the XY stage 105 is moved to the position where the multiple beams 20 can enter the Faraday cup 106. Then, the current value of the entire multiple beams 20, which are formed by the electron beam 200 emitted from the electron gun 201 and reached the position on the surface of the target object, is detected by the Faraday cup 106. The signal detected by the Faraday cup 106 is output to the current detection circuit 136, and converted into digital data to be output to the control computer 110. In the control computer 110, the luminance measurement unit 52 calculates a current density J of the entire multiple beams 20. The current density J can be calculated by dividing a measured current value by the total of aperture areas of a plurality of holes 22 in the shaping aperture array substrate 203.

In the determination step (S110), the luminance determination unit 54 determines whether an adjusted luminance is equal to or greater than a threshold. If the luminance is equal to or greater than the threshold, it proceeds to the current density distribution measurement step (S120). If the luminance is not equal to or greater than the threshold, it proceeds to the emission current determination step (S111).

In the emission current determination step (S111), the determination unit 51 determines whether the present emission current Emi is equal to or greater than the maximum value Emax. The value of the emission current Emi can be obtained as a current value detected by the ammeter 238. It is preferable that the maximum value Emax of the emission current Emi is set in advance for each cathode temperature T. If the present emission current Emi is equal to or greater than the maximum value Emax, it proceeds to the cathode temperature determination step (S113). If the present emission current Emi is less than the maximum value Emax, it proceeds to the emission current increase step (S112).

In the emission current increase step (S112), the emission current setting unit 72 increases the emission current from the present emission current Emi in order to increase the current density J (luminance) of the entire multiple beams 20. Specifically, it operates as follows. First, the emission current setting unit 72 sets a new emission current Emi by adding a current width ΔEmi, which has been set in advance, to the present emission current Emi. The electrostatic electrode voltage control unit 74 changes an electrostatic electrode voltage V so that a new emission current Emi can be obtained. The electrostatic electrode voltage control unit 74 controls the electrostatic electrode voltage power circuit 234 to change the present electrostatic electrode voltage V to be the positive side (ground potential side), for example. The electrostatic electrode voltage power circuit 234 applies a new electrostatic electrode voltage V to the electrostatic electrode 224. Here, the electrostatic electrode voltage V indicates a potential difference between a negative potential to be applied to the cathode 222 and a negative potential to be applied to the electrostatic electrode 224.

When it returned to the luminance measurement step (S102), each step from the luminance measurement step (S102) to the emission current increase step (S112) is repeated until the luminance becomes equal to or greater than the threshold, or the emission current Emi becomes equal to or greater than the maximum value Emax.

By this, the current density J (luminance) of the entire multiple beams 20 is adjusted to be a current density threshold Jth. Alternatively, in the range in which the emission current Emi can be increased, an adjustment is made so that the current density J (luminance) of the entire multiple beams 20 may be close to the current density threshold Jth.

In addition to the adjustment of the luminance, it is more preferable to adjust electromagnetic lenses such as the illumination lens 202, the reducing lens 205, and the objective lens 207 so that the opening half-angle of each beam on the surface of the target object 101 may be within a predetermined range.

In the cathode temperature determination step (S113), the cathode temperature determination unit 63 determines whether a set cathode temperature T is the cathode temperature maximum Tmax which has been set in advance. If the set cathode temperature T is not the cathode temperature maximum Tmax having been set beforehand, it proceeds to the cathode temperature increase step (S114). If the set cathode temperature T is the cathode temperature maximum Tmax having been set beforehand, it proceeds to the cathode parts replacement step (S119).

In the cathode temperature increase step (S114), the cathode temperature addition unit 60 adds AT to the present cathode temperature T. The cathode temperature setting unit 70 sets a new cathode temperature T which has been obtained by increasing the present cathode temperature T by ΔT. The cathode temperature T is increased by per reference temperature width ΔT which has been set in advance. The cathode temperature control unit 76 (temperature increase unit) controls the filament power supply circuit 231 so that the cathode temperature may be a set cathode temperature T. Thereby, the cathode temperature is controlled to be a newly set cathode temperature T which has been increased by ΔT. With respect to the reference temperature width ΔT, it is preferable to be set within the range of 10 to 50 degrees C. For example, it is set to 20 degrees C. Then, the electrostatic electrode voltage control unit 74 changes the electrostatic electrode voltage V so that a set emission current Emi can be obtained at a newly set cathode temperature T. For example, the electrostatic electrode voltage V is changed to the negative side.

In the cathode temperature determination step (S116), the cathode temperature determination unit 62 determines whether a set cathode temperature T is over the cathode temperature maximum Tmax which has been set beforehand. If the set cathode temperature T is greater than the cathode temperature maximum Tmax, it proceeds to the cathode temperature correction step (S118). If the set cathode temperature T is less than the cathode temperature maximum Tmax, it returns to the luminance measurement step (S102), and repeatedly performs each step from the luminance measurement step (S102) to the determination step (S116) until the luminance becomes equal to or greater than the threshold or the set cathode temperature T becomes greater than the cathode temperature maximum Tmax. In other words, after the reference temperature width ΔT is added in the cathode temperature increase step (S114), the luminance of the entire electron beam is measured again.

In the cathode temperature correction step (S118), when the set cathode temperature T is greater than the cathode temperature maximum Tmax, the cathode temperature correction unit 64 corrects the present cathode temperature T to be the cathode temperature maximum Tmax. The cathode temperature setting unit 70 sets the corrected cathode temperature as a new cathode temperature T. The cathode temperature control unit 76 controls the filament power supply circuit 231 so that the cathode temperature may be a set cathode temperature T. Thereby, the cathode temperature T is controlled to be the cathode temperature maximum Tmax. Then, the electrostatic electrode voltage control unit 74 changes the electrostatic electrode voltage V so that a set emission current Emi can be obtained at the cathode temperature T being the maximum Tmax. Since it is difficult to increase the cathode temperature more, it returns, at the cathode temperature T being the maximum Tmax, to the luminance measurement step (S102), and it is checked whether a desired luminance and a desired current density distribution can be obtained. In other words, after the reference temperature width ΔT is added in the cathode temperature increase step (S114), the luminance of the entire electron beam is measured again.

When determined that the cathode temperature T which was set in the cathode temperature determination step (S113) is the cathode temperature maximum Tmax having been set in advance, since it is in the state where a desired luminance or a desired current density distribution was not obtained even though the set cathode temperature T is the cathode temperature maximum Tmax, the parts of the cathode need to be replaced with new ones in the cathode parts replacement step (S119), and then, it returns to the luminance measurement step (S102) to start the adjustment again. For example, if cathode parts have been degraded, there is a case where a desired current density or a current density distribution cannot be satisfied even if the cathode temperature is increased to the upper limit temperature. In that case, after replacing the cathode parts, adjustment is started again. In such a case, it is preferable that the cathode temperature is started from the initial value of the temperature being sufficiently lower than the cathode temperature maximum Tmax.

In the current density distribution measurement step (S120), the current density distribution measurement unit 56 measures a current density distribution U of the multiple beams 20 (electron beam). In other words, the current density distribution measurement unit 56 measures the current density distribution U of the multiple beams 20 to reach the target object 101. First, the current density distribution measurement unit 56 measures a current density J (i, j) of an electron beam, for each of a plurality of sub-regions obtained by dividing the irradiation region of an electron beam to reach the target object 101. (i, j) indicates an index of the sub-region. In the first embodiment, since the multiple beams 20 is used as the electron beam, the current density distribution measurement unit 56 divides the multiple beams 20 into a plurality of beam array groups (sub-regions) each composed of neighboring beams. For example, the current density distribution measurement unit 56 divides the beam array region of the multiple beams 20 into k×k sub-regions, and divides the multiple beams 20 into a plurality of beam array groups each composed of beams in the sub-region concerned. Then, the current value of each beam array group is detected by the Faraday cup 106. First, the XY stage 105 is moved to the position where a target beam array group can enter the Faraday cup 106. The current value of the target beam array group reached the position on the surface of the target object is detected by the Faraday cup 106. The signal detected by the Faraday cup 106 is output to the current detection circuit 136, and converted into digital data to be output to the control computer 110. In the control computer 110, the current density distribution measurement unit 56 measures (calculates), for each beam array group, the current density J of the target beam array group. The current density J of the target beam array group can be calculated by dividing a measured current value by the total of aperture areas of a plurality of holes 22 for each beam array group in the shaping aperture array substrate 203.

Next, the current density distribution measurement unit 56 measures (calculates) the current density distribution U by using the current density J of each of a plurality of sub-regions. Specifically, the current density distribution measurement unit 56 calculates the current density distribution U by using the current density J of each beam array group. The current density distribution U is measured when the luminance is equal to or greater than a threshold. The measured current density distribution U is stored in the storage device 140, for example.

In the feature amount calculation step (S130), the feature amount calculation unit 58 calculates a feature amount K(i, j) of the measured current density distribution U. The feature amount K(i, j) is calculated for each beam array group (sub-region). As the feature amount K(i, j), a ratio of the current density J(i, j) to the maximum Jmax of the current density J(i, j) of each beam array group (sub-region) of the current density distribution U is used. The feature amount K can be defined by the equation (1) below.

K(i, j)=J(i, j)/Jmax (1)

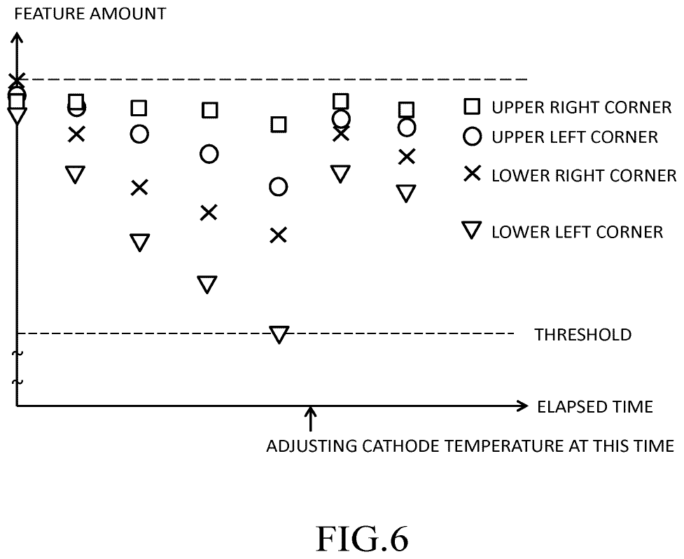

FIG. 6 is an illustration showing an example of temporal transition of a feature amount according to the first embodiment. FIG. 6 shows an example of temporal transition of the feature amount at four corners (upper right corner, upper left corner, lower right corner, and lower left corner) of the rectangular multiple beams 20. As described above, the current density distribution U of an electron beam has a tendency that the current density J decreases at the outer peripheral portion. In the example of FIG. 6, it turns out that, along with the elapsed time, the feature amount of each beam array group at the lower right corner and the lower left corner remarkably decreases, for example.

In the determination step (S132), the determination unit 59 determines whether there exists a feature amount K(i, j) outside the threshold range. Specifically, the determination unit 59 determines whether a feature amount K(i, j) equal to or less than a threshold Kth exists. It is preferable that the threshold Kth is set to be in the range of 0.95 to 0.99 (95% to 99%), for example. If the feature amount K(i, j) equal to or less than the threshold Kth does not exist, it finishes the electron beam adjustment and proceeds to the writing step (S140). If the feature amount K(i, j) equal to or less than the threshold Kth exists, it proceeds to the cathode temperature increase step (S114), and until no feature amount K(i, j) equal to or less than the threshold Kth exists, each step from the luminance measurement step (S102) to the determination step (S132) is repeated. Thus, when the feature amount K (i, j) is outside the threshold range, the cathode temperature control unit 76 (temperature increase unit) increases the temperature of the cathode 222 (electron beam emission source).

In the case of FIG. 6, when the feature amount K(i, j) of the beam array group at the lower left corner reaches the threshold Kth, it proceeds to the cathode temperature increase step (S114), and by increasing the cathode temperature T, the feature amount of each sub-region is increased, thereby retrieving the state nearly immediately after the last electron beam adjustment.

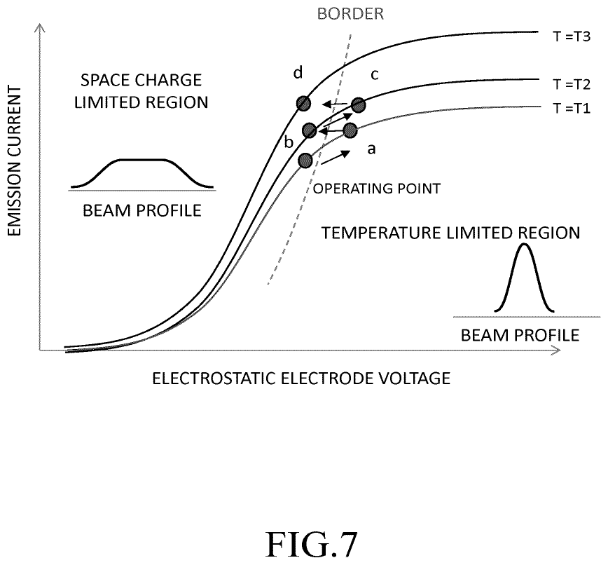

FIG. 7 is an illustration showing an example of the course of an operating point of an electron gun due to electron beam adjustment according to the first embodiment.

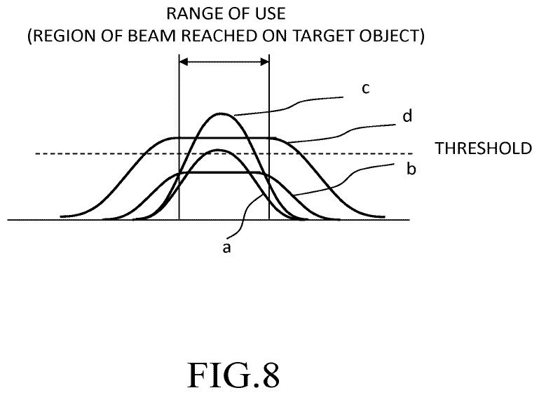

FIG. 8 is an illustration showing an example of transition of a current density distribution due to electron beam adjustment according to the first embodiment.

FIG. 7 shows a relationship among an emission current Emi, an electrostatic electrode voltage V and a cathode temperature T. The ordinate axis represents an emission current Emi, and the abscissa axis represents an electrostatic electrode voltage V. In FIG. 7, for each cathode temperature, a characteristic curve between an emission current and an electrostatic electrode voltage is shown. The cathode temperature T has the relation T3>T2>T1. The border between the space charge limited region and the temperature limited region is shown by a dotted line. The electrostatic electrode voltage value at the border between the space charge limited region and the temperature limited region changes depending on a cathode temperature. Generally, the lower, the cathode temperature is, the smaller towards the negative side, the electrostatic electrode voltage which is a border becomes. The operating point which drives the electron gun 201 drive is generally set at the position close to the border between the space charge limited region and the temperature limited region, and not within the temperature limited region.

If an electron beam is emitted in the temperature limited region, the current density distribution U of the beam becomes a steep with low uniformity, and a portion with locally high intensity is generated in the beam current density distribution U. In contrast, if an electron beam is emitted in the space charge limited region, the current density distribution U of the beam becomes a shape with high uniformity. Regarding the same emission current, there is a case where a locally high intensity of the current density distribution U of the beam in the temperature limited region is higher than the intensity of a uniform portion of the current density distribution U of the beam in the space charge limited region.

In the case of driving the electron gun 201 at the operating point at the cathode temperature T1, if the luminance (here, the current density of the entire multiple beams) is less than a threshold, the emission current Emi is increased. Thereby, for example, the operating point enters the temperature limited region, and the current density distribution U becomes a steep with low uniformity (distribution a in FIG. 8). In such a state, although the luminance (here, the current density of the entire multiple beams) satisfies a threshold, the current density distribution U does not satisfy the conditions (here, the feature amount K(i, j) equal to or less than the threshold Kth exists). Then, the cathode temperature T is increased to T2. The electrostatic electrode voltage control unit 74 changes the electrostatic electrode voltage V so that a set emission current Emi can be obtained. Thereby, for example, the operating point returns to the space charge limited region, and the current density distribution U becomes highly uniform (distribution b in FIG. 8). Thus, the current density distribution U satisfies the conditions. However, now, the luminance becomes insufficient. Then, the emission current

Emi is increased at the cathode temperature T2. By this, for example, the operating point enters the temperature limited region, and the current density distribution U becomes a steep with low uniformity (distribution c in FIG. 8). Thereby, although the luminance satisfies the threshold, the current density distribution U does not satisfy the conditions. Then, the cathode temperature T is increased to T3. The electrostatic electrode voltage control unit 74 changes the electrostatic electrode voltage V so that a set emission current Emi can be obtained. Thereby, for example, the operating point returns to the space charge limited region, and the current density distribution U becomes highly uniform (distribution d in FIG. 8). Thus, while satisfying the conditions of the luminance, the current density distribution U satisfies the conditions (here, there is no feature amount K(i, j) equal to or less than the threshold Kth).

As described above, electron beam adjustment where the current density distribution U satisfies the conditions can be performed.

Next, a writing processing method is explained below.

In the writing step (S140), first, the writing data processing unit 40 reads writing data stored in the storage device 140, and generates writing time data to perform writing with multiple beams. The writing control unit 42 rearranges irradiation time data in the order of shot in accordance with a writing sequence. Then, the irradiation time data is transmitted to the deflection control circuit 130 in the order of shot. The deflection control circuit 130 outputs deflection control signals to the DAC amplifier units 132 and 134 in the order of shot while outputting a blanking control signal to the blanking aperture array mechanism 204 in the order of shot. The writing mechanism 150 controlled by the writing control unit 42 writes a pattern on the target object 101, using electron beams emitted from the electron gun 201 and having been beam-adjusted. In other words, the writing mechanism 150 writes a pattern on the target object 101 by using the multiple beams 20 whose feature amount K(i, j) is within the range of a threshold.

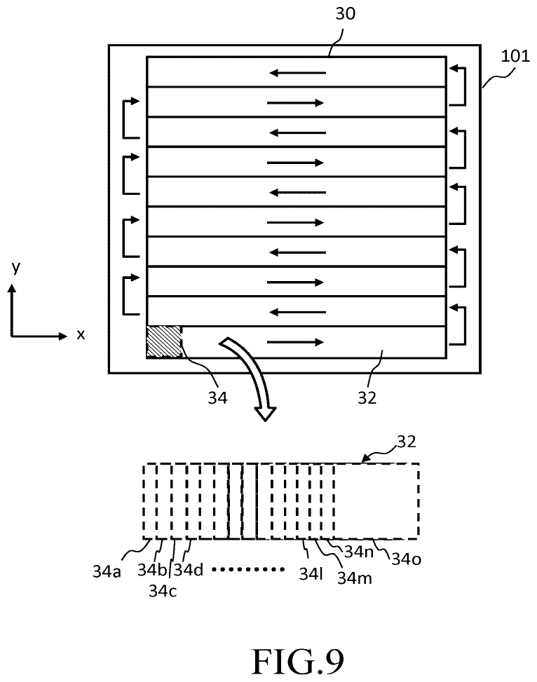

FIG. 9 is a conceptual diagram illustrating an example of a writing operation according to the first embodiment. As shown in FIG. 9, a writing region 30 of the target object 101 is virtually divided, for example, by a predetermined width in the y direction into a plurality of stripe regions 32 in a strip form. First, the XY stage 105 is moved to make an adjustment such that an irradiation region 34 which can be irradiated with one shot of the multiple beams 20 is located at the left end of the first stripe region 32 or at a position further left than the left end, and then writing is started. When writing the first stripe region 32, the XY stage 105 is moved, for example, in the -x direction, so that the writing may proceed relatively in the x direction. The XY stage 105 is moved, for example, continuously at a constant speed. After writing the first stripe region 32, the stage position is moved in the -y direction to make an adjustment such that the irradiation region 34 is located at the right end of the second stripe region 32 or at a position further right than the right end to be thus located relatively in the y direction. Then, by moving the XY stage 105 in the x direction, for example, writing proceeds in the -x direction. That is, writing is performed while alternately changing the direction, such as performing writing in the x direction in the third stripe region 32, and in the -x direction in the fourth stripe region 32, thereby reducing the writing time. However, the writing operation is not limited to the writing while alternately changing the direction, and it is also preferable to perform writing in the same direction when writing each stripe region 32. By one shot of multiple beams having been formed by passing through the holes 22 in the shaping aperture array substrate 203, a plurality of shot patterns up to the number of the holes 22 are maximally formed at a time. Furthermore, although FIG. 9 shows the case where writing is performed once for each stripe region 32, it is not limited thereto. It is also preferable to perform multiple writing which writes the same region multiple times. In performing the multiple writing, preferably, the stripe region 32 of each pass is set while shifting the position.

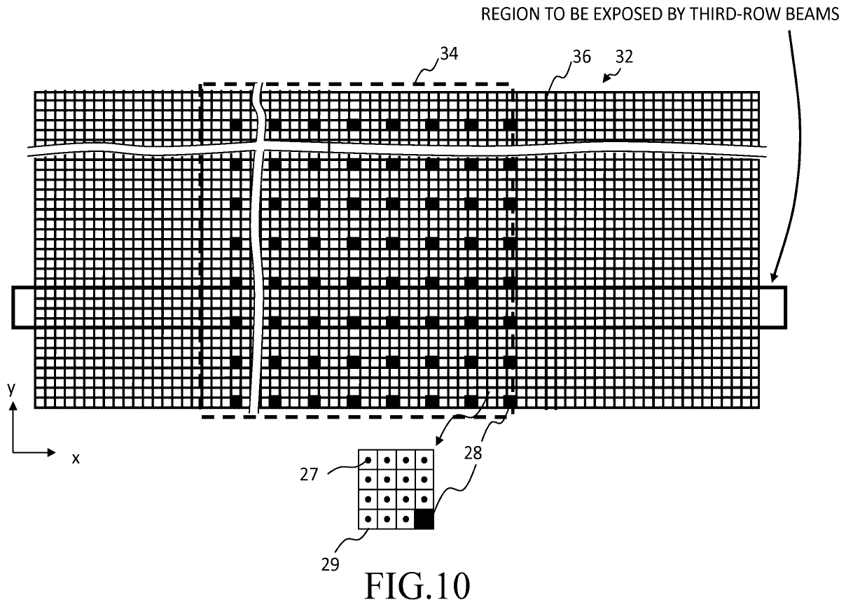

FIG. 10 is an illustration showing an example of an irradiation region of multiple beams and a pixel to be written (writing target pixel) according to the first embodiment. In FIG. 10, in the stripe region 32, there are set a plurality of control grids 27 (design grids) arranged in a grid form at the beam size pitch of the multiple beams 20 on the surface of the target object 101, for example.

Preferably, they are arranged at a pitch of around 10 nm. The plurality of control grids 27 serve as design irradiation positions of the multiple beams 20. The arrangement pitch of the control grid 27 is not limited to the beam size, and may be any size that can be controlled as a deflection position of the deflector 209 regardless of the beam size. Then, a plurality of pixels 36, each of which is centering on each control grid 27, are set by virtually dividing into a mesh form by the same size as that of the arrangement pitch of the control grid 27. Each pixel 36 serves as an irradiation unit region per beam of the multiple beams. FIG. 10 shows the case where the writing region of the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the irradiation region 34 can be defined by the value obtained by multiplying the beam pitch (pitch between beams) in the x direction of the multiple beams 20 by the number of beams in the x direction. The y-direction size of the irradiation region 34 can be defined by the value obtained by multiplying the beam pitch in the y direction of the multiple beams 20 by the number of beams in the y direction. The width of the stripe region 32 is not limited to this. Preferably, the width of the stripe region 32 is n times (n being an integer of one or more) the size of the irradiation region 34. FIG. 10 shows the case where the multiple beams of 512×512 (rows×columns) are simplified to 8×8 (rows×columns). In the irradiation region 34, there are shown a plurality of pixels 28 (beam writing positions) which can be irradiated with one shot of the multiple beams 20. In other words, the pitch between adjacent pixels 28 is the pitch between beams of the design multiple beams. In the example of FIG. 10, one sub-irradiation region 29 is a region surrounded by beam pitches. In the case of FIG. 10, each sub-irradiation region 29 is composed of 4×4 pixels.

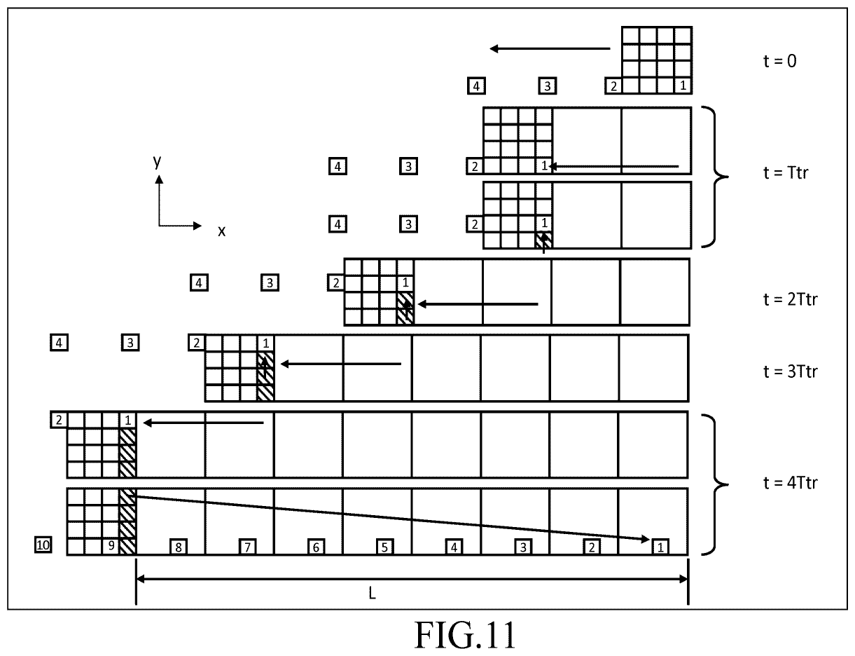

FIG. 11 is an illustration for explaining an example of a writing method of multiple beams according to the first embodiment. FIG. 11 shows a portion of the sub-irradiation region 29 to be written by each of beams at the coordinates (1, 3), (2, 3), (3, 3), . . . , (512, 3) in the y-direction third row from the bottom in the multiple beams for writing the stripe region 32 shown in FIG. 9. In the example of FIG. 11, while the XY stage 105 moves the distance of eight beam pitches, four pixels are written (exposed), for example. In order that the relative position between the irradiation region 34 and the target object 101 may not be shifted by the movement of the XY stage 105 while these four pixels are written (exposed), the irradiation region 34 is made to follow the movement of the XY stage 105 by collective deflection of all of the multiple beams 20 by the deflector 208. In other words, tracking control is performed. In the case of FIG. 11, one tracking cycle is executed by writing (exposing) four pixels while shifting, per shot, the irradiation target pixel 36 in the y direction during a movement by the distance of eight beam pitches.

Specifically, the writing mechanism 150 irradiates each control grid 27 with a corresponding beam in an ON state in the multiple beams 20 during a writing time (irradiation time or exposure time) corresponding to each control grid 27 within a maximum irradiation time Ttr of the irradiation time of each beam of the multiple beams of the shot concerned. The maximum irradiation time Ttr is set in advance. Although the time obtained by adding a settling time of beam deflection to the maximum irradiation time Ttr actually serves as a shot cycle, the settling time of beam deflection is omitted here to indicate the maximum irradiation time Ttr as the shot cycle. After one tracking cycle is completed, the tracking control is reset so as to swing back (return) the tracking position to the starting position of a next tracking cycle.

Since writing of the pixels in the first column from the right of each sub-irradiation region 29 has been completed, in the next tracking cycle after resetting the tracking, first, the deflector 209 performs deflection such that the writing position of each corresponding beam is adjusted (shifted) to the control grid 27 of the pixel second from the right in the bottom row of each sub-irradiation region 29.

As described above, in the state where the relative position of the irradiation region 34 to the target object 101 is controlled by the deflector 208 to be the same (unchanged) position during the same tracking cycle, each shot is carried out while performing shifting from a control grid 27 (a pixel 36) to another control grid 27 (another pixel 36) by the deflector 209. Then, after finishing one tracking cycle and returning the tracking position of the irradiation region 34, the first shot position is adjusted to the position shifted by, for example, one control grid (one pixel) as shown in the lower part of FIG. 11, and each shot is performed shifting from one control grid (one pixel) to another control grid (another pixel) by the deflector 209 while executing a next tracking control. By repeating this operation during writing the stripe region 32, the position of the irradiation region 34 is shifted sequentially, such as from 34a to 34o as shown in the lower part of FIG. 9, to perform writing of the stripe region concerned.

Based on the writing sequence, it is determined which beam of the multiple beams irradiates which control grid 27 (pixel 36) on the target object 101. Supposing that the sub-irradiation region 29 is composed of n×n pixels, n control grids (n pixels) are written by one tracking operation. Then, by the next tracking operation, other n pixels in the same n×n pixel region are similarly written by a different beam from the one used above. Thus, writing is performed for each n pixels by a different beam each time in n-time tracking operations, thereby writing all of the pixels in one region of n×n pixels. With respect also to other sub-irradiation regions 29 each composed of n×n pixels in the irradiation region of multiple beams, the same operation is executed at the same time so as to perform writing similarly.

The beam adjustment described above is performed at the time when the target object 101 is not being written. For example, the beam adjustment is performed after completing writing a certain target object and before starting writing the next target object. Alternatively, even after starting writing the target object and before finishing the writing it, the beam adjustment is performed after completing writing the stripe region 32 and before starting writing the next stripe region 32.

According to the first embodiment, as described above, in multiple beam writing, uniformity of a current density distribution in the irradiation region of irradiating multiple beams 20 can be improved. Therefore, a necessary incident dose can be obtained at all of the irradiation regions of the multiple beams 20.

### Second Embodiment

Although in the first embodiment the configuration in which multiple beams are used is described, it is not limited thereto. A second embodiment describes a configuration which uses a single beam. The contents of the second embodiment are the same as those of the first embodiment except what is particularly described below.

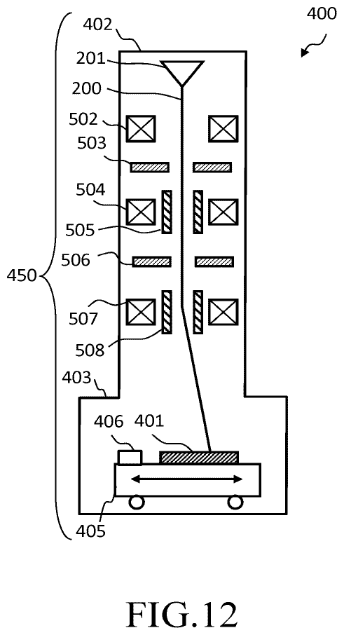

FIG. 12 is a conceptual diagram showing a configuration of a writing apparatus according to the second embodiment. As shown in FIG. 12, a writing apparatus 400 includes a writing mechanism 450. The writing apparatus 400 is an example of an electron beam writing apparatus. The writing mechanism 450 includes an electron optical column 402 and a writing chamber 403. In the electron optical column 402, there are disposed the electron gun 201, an illumination lens 502, a first shaping aperture substrate 503, a projection lens 504, a deflector 505, a second shaping aperture substrate 506, an objective lens 507, and a deflector 508.

In the writing chamber 403, an XY stage 405 is arranged movably. On the XY stage 405, a target object 401 is placed. Similarly to the first embodiment, the target object 401 may be a photomask substrate and the like. The mask substrate may be a mask blank on which no pattern has yet been written. Furthermore, on the XY stage 405, a Faraday cup 406 is arranged.

In FIG. 12, illustration of the control system circuit is omitted. In the writing apparatus 400 according to the second embodiment, the same configuration as that of the control system 160 shown in FIG. 1 is arranged. For example, there are included the control computer 110, the memory 112, the monitor 114, the electron gun power supply device 120, the deflection control circuit 130, the DAC amplifier units 132 and 134, the current detection circuit 136, the stage position detector 139, and the storage device 140.

In FIG. 12, description of configuration elements other than those necessary for explaining the second embodiment is omitted. It goes without saying that other configuration elements generally needed for the writing apparatus 400 may also be included therein.

The electron beam 200 emitted from the electron gun 201 (electron emission source) irradiates the whole of the first shaping aperture substrate 503 which has a quadrangular, such as rectangular, hole by the illumination lens 502. At this point, first, the electron beam 200 is shaped to be a rectangle. The electron beam 200 of the first aperture image having passed through the first shaping aperture substrate 503 is projected onto the second shaping aperture substrate 506 by the projection lens 504. The position of the first aperture image on the second shaping aperture substrate 506 is deflection-controlled by the deflector 505 so as to change the shape and dimension of the beam. Thereby, the electron beam 200 is variably shaped. Generally, the shape and/or dimension of a beam is changed for each shot. The electron beam 200 of the second aperture image having passed through the second shaping aperture substrate 506 is focused by the objective lens 507, and deflected by the deflector 508. Consequently, a shot of the shaped electron beam 200 is applied to a desired position on the target object 401 placed on the XY stage 405. The XY stage 105 moves continuously. Thus, the writing apparatus 400 performs writing while the XY stage 405 is continuously moving. Alternatively, the stage may move in a step and repeat manner. In that case, the writing apparatus 400 performs writing while the XY stage 105 is stopped during the step and repeat movement.

Also in the case of single beam, a current density distribution is generated in the emitted electron beam 200 as shown in FIG. 4. For example, the first aperture image having passed through the first shaping aperture substrate 503 corresponds to the case of FIG. 4. According to the second embodiment, since the electron beam is variably shaped for each shot, one of the four corners of the first aperture image are generally used for the electron beam to reach the surface of the target object 401. Therefore, a problem occurs in the current density distribution U.

The flowchart showing an example of main steps of a writing method according to the second embodiment is the same as that of FIG. 5.

In the luminance measurement step (S102), the luminance measurement unit 52 measures luminance of the electron beam 200. Here, as a parameter indicating the luminance, a current density J of the entire electron beam 200 to reach the target object 101 is measured. Concretely, first, the XY stage 105 is moved to the position where the electron beam 200 can enter the Faraday cup 106. Then, the current value of the entire electron beam 200 emitted from the electron gun 201, having passed through the first shaping aperture substrate 503, and reached the position on the surface of the target object is detected by the Faraday cup 106. The signal detected by the Faraday cup 106 is output to the current detection circuit 136, and converted into digital data to be output to the control computer 110. In the control computer 110, the luminance measurement unit 52 calculates a current density J of the entire electron beam 200. The current density J can be calculated by dividing a measured current value by the aperture area of the first shaping aperture substrate 503. Here, the deflector 505 is controlled so that the entire electron beam 200 having passed through the first shaping aperture substrate 503 may pass through the shaping aperture of the second shaping aperture substrate 506.

The contents of each of the determination step (S110), the emission current determination step (S111), the emission current increase step (S112), the cathode temperature increase step (S114), the cathode temperature determination step (S116), and the cathode temperature correction step (S118) are the same as those of the first embodiment.

In the current density distribution measurement step (S120), the current density distribution measurement unit 56 measures a current density distribution U of the electron beam 200 (electron beam). In other words, the current density distribution measurement unit 56 measures the current density distribution U of the electron beam 200 to reach the target object 101. First, the current density distribution measurement unit 56 measures a current density J(i, j) of an electron beam, for each of a plurality of sub-regions obtained by dividing the irradiation region of an electron beam to reach the target object 101. (i, j) indicates an index of the sub-region. In the second embodiment, since a single beam is used as the electron beam, the current density distribution measurement unit 56 divides a single beam into a plurality of sub-regions.

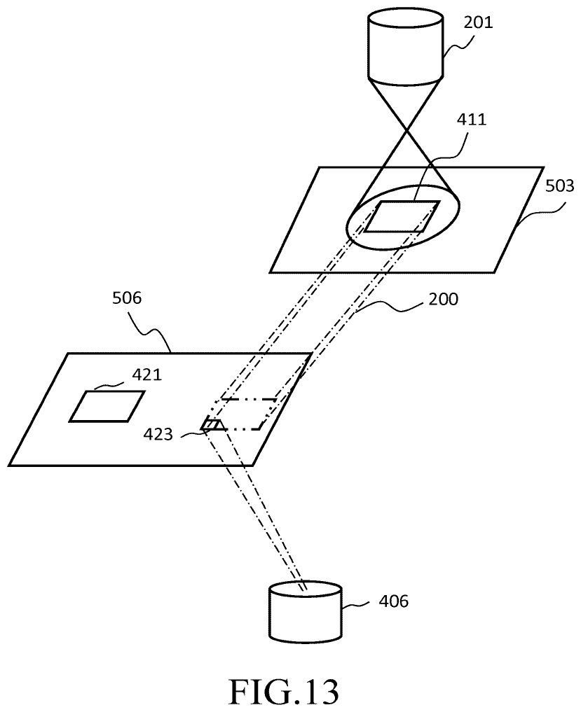

FIG. 13 is an illustration for explaining a method of measuring a current density distribution according to the second embodiment. In FIG. 13, a rectangular aperture 411 is formed in the first shaping aperture substrate 503. A shaping aperture 421 is formed in the second shaping aperture substrate 506. Although FIG. 13 shows the case of the shaping aperture 421 being a rectangle, it is not limited thereto. Other shape may also be formed. Furthermore, in the second shaping aperture substrate 506, a sub-region aperture 423 is formed on a different position from that of the shaping aperture 421. While the shaping aperture 421 has a size through which the entire first aperture image can pass, the sub-region aperture 423 is formed in a sub-region size of the case of dividing the rectangular irradiation region of the first aperture image on the second shaping aperture substrate 506 into k×k sub-regions. Therefore, the sub-region aperture 423 makes only a partial beam in one sub-region in a plurality of sub-regions of the first aperture image pass through.

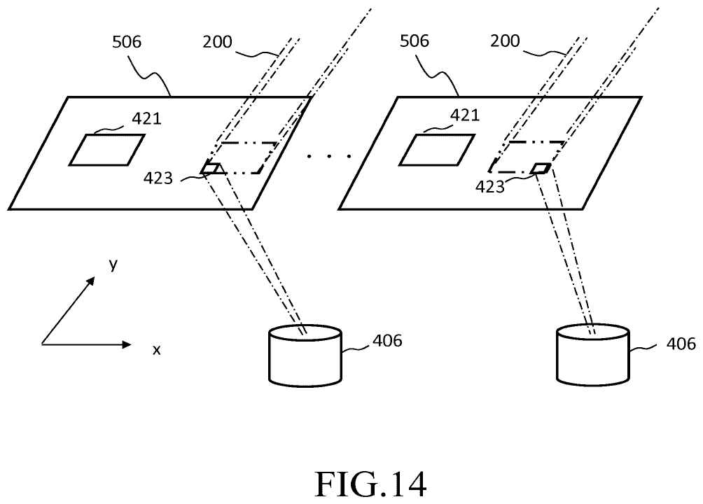

FIG. 14 is an illustration explaining a procedure for measuring a current density distribution according to the second embodiment. As shown in FIG. 14, by moving the sub-region, which irradiates the sub-region aperture 423, by beam deflection by the deflector 505, it is possible to make a partial beam in each sub-region in the electron beam 200 individually pass through. A current value is detected for each sub-region by the Faraday cup 106. The XY stage 405 is moved to the position where a partial beam in a target sub-region can enter the Faraday cup 106. Then, the current value of a partial beam in a target sub-region reached on the surface of the target object is detected by the Faraday cup 106. The signal detected by the Faraday cup 106 is output to the current detection circuit 136, and converted into digital data to be output to the control computer 110. In the control computer 110, the current density distribution measurement unit 56 measures (calculates), for each sub-region, a current density J of a partial beam in a target sub-region. The current density J of a partial beam in a target sub-region can be calculated by dividing a measured current value by the aperture area of the sub-region aperture 423.

Next, the current density distribution measurement unit 56 measures (calculates) a current density distribution U by using the current density J of each sub-region on a plurality of sub-regions. The measured current density distribution U is stored in the storage device 140, for example.

In the feature amount calculation step (S130), the feature amount calculation unit 58 calculates a feature amount K(i, j) of the measured current density distribution U. The feature amount K(i, j) is calculated for each sub-region. As the feature amount K(i, j), a ratio of the current density J(i, j) of each beam array group to the maximum Jmax of the current density J(i, j) of each sub-region of the current density distribution U is used. The feature amount K can be defined by the equation (1) described above.

An example of temporal transition of a feature amount shown in FIG. 6 may bring the same result even in the case of a single beam. The result of FIG. 6 corresponds to an example of temporal transition of the feature amount at the four corners (upper right corner, upper left corner, lower right corner, and lower left corner) of the electron beam 200 having passed through the first shaping aperture array substrate 503. Also here, along with the elapsed time, the feature amount of the sub-region at the lower right corner and the lower left corner may remarkably decrease, for example.

The contents of the determination step (S132) of the second embodiment are the same as those of the first embodiment.

In the writing step (S140), the writing mechanism 150 controlled by the writing control unit 42 writes a pattern on the target object 101, using the electron beam 200 emitted from the electron gun 201 and having been beam-adjusted. In other words, the writing mechanism 150 writes a pattern on the target object 101 by using the electron beam 200 whose feature amount K(i, j) is within the range of a threshold.

According to the second embodiment, as described above, in single beam writing, uniformity of a current density distribution in the irradiation region of an irradiating beam can be improved. Therefore, a necessary incident dose can be obtained at all of the irradiation regions of the electron beam 200.

Embodiments have been explained referring to specific examples described above. However, the present invention is not limited to these specific examples.

Functions of processing described in the first embodiment may be executed by a computer. A program for causing a computer to implement such functions of processing may be stored in a non-transitory tangible computer-readable storage medium such as a magnetic disk drive.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any electron beam adjustment method, electron beam writing apparatus, and program (or non-transitory computer-readable storage medium storing a program) that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electron beam adjustment method comprising:
measuring a current density distribution of an electron beam to reach a target object;
calculating a feature amount of a measured current density distribution; and
increasing, in a case of the feature amount being outside a range of a threshold, a temperature of an electron beam emission source.

2. The method according to claim 1, wherein, as the electron beam emission source, a cathode of an electron gun including at least one electrostatic electrode which is directly below the cathode is used.

3. The method according to claim 1, wherein the target object is irradiated with the electron beam, further comprising:
measuring a current density of the electron beam, for each sub-region of a plurality of sub-regions obtained by dividing an irradiation region of the electron beam to reach the target object, wherein
the current density distribution is measured by using the current density of each of the plurality of sub-regions.

4. The method according to claim 3, wherein, as the feature amount, a ratio of the current density to a maximum value of the current density in the current density distribution of each of the sub-regions is used.

5. The method according to claim 1, further comprising:
measuring luminance of an entire electron beam, wherein the current density distribution is measured in a case of the luminance being one of equal to and greater than a threshold.

6. The method according to claim 1, wherein the temperature is increased by per reference temperature width having been set in advance.

7. The method according to claim 5, further comprising:
determining, in a case of the luminance being less than the threshold, whether a present emission current is one of equal to and greater than a maximum value; and
increasing, in a case of the present emission current being less than the maximum value as a result of the determining, a current density of the electron beam by increasing an emission current from the present emission current.

8. The method according to claim 7, further comprising:
determining, in a case of the present emission current being one of equal to and greater than the maximum value as a result of the determining, whether a temperature set in the electron beam emission source is a temperature maximum value which has been set in advance;
adding, in a case of the temperature having been set is not the temperature maximum value, a reference temperature width which has been set in advance to a present temperature set to the electron beam emission source; and
measuring, after the adding the reference temperature width, luminance of the entire electron beam again.

9. The method according to claim 8, wherein adjustment is performed not only at a time of starting using a cathode as the electron beam emission source but also during an operation.

10. An electron beam writing apparatus comprising:
a current density distribution measurement circuit configured to measure a current density distribution of an electron beam to reach a target object;
a feature amount calculation circuit configured to calculate a feature amount of a measured current density distribution;
a temperature increase circuit configured to increase, in a case of the feature amount being outside a range of a threshold, a temperature of an electron beam emission source; and
a writing mechanism configured to write a pattern on the target object by using the electron beam whose feature amount is within the range of the threshold.

11. A non-transitory computer-readable storage medium storing a program for causing a computer to execute processing comprising:
measuring a current density distribution of an electron beam to reach a target object;
storing a measured current density distribution in a storage device;
reading the measured current density distribution from the storage device and calculating a feature amount of the measured current density distribution; and
increasing, in a case of the feature amount being outside a range of a threshold, a temperature of an electron beam emission source.
